(19) United States
(12) Patent Application Publication
(10) Pub. No.: US 2025/0384916 A1
(43) Pub. Date: Dec. 18, 2025

(54) MEMORY WITH DATA DESTRUCTION CIRCUITRY, AND ASSOCIATED SYSTEMS, DEVICES, AND METHODS

(71) Applicant: Micron Technology, Inc., Boise, ID (US)

(72) Inventors: Jing Wen, Taichung (TW); Debra M. Bell, Boise, ID (US); Bo Sheng Zheng, Taichung (TW); Chen-Whai Sheng, Taichung (TW)

(21) Appl. No.: 19/222,401

(22) Filed: May 29, 2025

Related U.S. Application Data
(60) Provisional application No. 63/661,212, filed on Jun. 18, 2024.

(51) Int. Cl. G11C 11/4078; G11C 11/4072; G11C 11/408

(52) U.S. Cl. CPC G11C 11/4078; G11C 11/4072; G11C 11/4085

(57) ABSTRACT

Memory with data destruction circuitry (and associated systems, devices, and methods) is disclosed herein. In one embodiment, a memory device includes a memory array having memory cells arranged at intersections of corresponding word lines and corresponding bit lines. The memory device can be configured to detect that a data destruction condition is met. The data destruction condition can indicate that data stored in the memory cells is to be destroyed. Based at least in part on detecting that the data destruction condition is met, the memory device can (a) drive the corresponding word lines toward a first voltage to couple storage elements of the memory cells to the corresponding bit lines, and (b) charge or discharge the storage elements, via the corresponding bit lines, such that the data stored in the memory cells is destroyed.

### CROSS-REFERENCE TO RELATED APPLICATION(S)

The present application claims priority to U.S. Provisional Patent Application No. 63/661,212, filed Jun. 18, 2024, the disclosure of which is incorporated herein by reference in its entirety.

This application contains subject matter related to an U.S. Patent Application by Jing Wen et al. titled “MEMORY WITH MEMORY CELL INITIALIZATION CIRCUITRY, AND ASSOCIATED SYSTEMS, DEVICES, AND METHODS.” The related application is assigned to Micron Technology, Inc., and is identified as U.S. Patent Application No. 63/661,290, filed Jun. 18, 2024. The subject matter thereof is incorporated herein by reference thereto.

### TECHNICAL FIELD

The present disclosure generally relates to semiconductor devices. For example, several embodiments of the present disclosure are directed to memory devices with circuitry that, after the memory devices experience a power down event or a power loss event, destroy data stored to the memory devices.

### BACKGROUND

Memory devices are widely used to store information related to various electronic devices such as computers, wireless communication devices, cameras, digital displays, and the like. Memory devices are frequently provided as internal, semiconductor, integrated circuits, and/or external removable devices in computers or other electronic devices. There are many different types of memory, including volatile and non-volatile memory. Volatile memory, including static random-access memory (SRAM), dynamic random-access memory (DRAM), and synchronous dynamic random-access memory (SDRAM), among others, lose stored data after power supplied to the volatile memory is interrupted. In some cases, however, the data loss is not immediate. Thus, data remaining on the volatile memory after a power down or power loss event may still be retrievable from the volatile memory.

### BRIEF DESCRIPTION OF THE DRAWINGS

Many aspects of the present disclosure can be better understood with reference to the following drawings. The components in the drawings are not necessarily to scale. Instead, emphasis is placed on illustrating clearly the principles of the present disclosure. The drawings should not be taken to limit the disclosure to the specific embodiments depicted, but are for explanation and understanding only.

FIG. 1A is a partially schematic block diagram of a memory system configured in accordance with various embodiments of the present technology.

FIG. 1B is a partially schematic block diagram of a memory device configured in accordance with various embodiments of the present technology.

FIG. 2 illustrates a partially schematic diagram of data destruction circuitry coupled to a memory cell of a memory array, all of which are configured in accordance with various embodiments of the present technology.

FIG. 3 is a flowchart illustrating a method for destroying (or otherwise preempting access to) data in accordance with various embodiments of the present technology.

FIG. 4 is a schematic view showing a system comprising a semiconductor device assembly that can include memory devices configured in accordance with various embodiments of the present technology.

### DETAILED DESCRIPTION

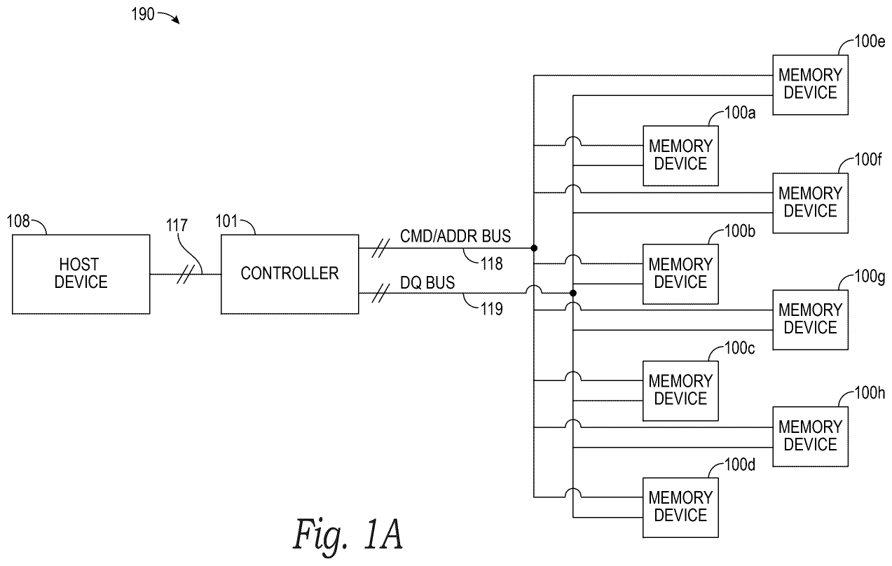

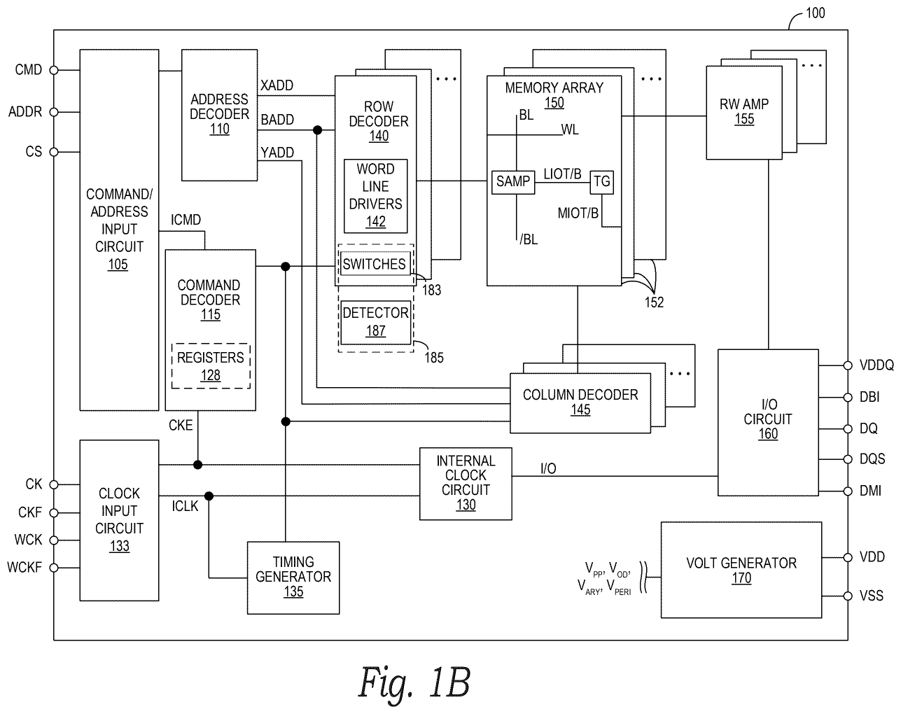

The present disclosure is generally directed to memory with data destruction circuitry and associated systems, devices, and methods. For example, several embodiments described in detail below are directed to memory devices that are configured to determine when a data destruction condition is met. The data destruction condition can indicate that data stored in memory cells of the memory devices is to be destroyed. Based at least in part on the determination, the memory devices can (a) drive word lines corresponding to the memory cells to a voltage that is usable to couple storage elements of the memory cells to corresponding bit lines, and (b) charge or discharge the storage elements of the memory cells via the corresponding bit lines to destroy or corrupt data stored on the storage elements. A person skilled in the art will understand that the technology may have additional embodiments and that the technology may be practiced without several of the details of the embodiments described below with reference to FIGS. 1A-4.

In the illustrated embodiments below, the memory devices and systems are primarily described in the context of devices incorporating DRAM storage media. Memory devices configured in accordance with other embodiments of the present technology, however, can include other types of memory devices and systems incorporating other types of storage media, including PCM, SRAM, FRAM, RRAM, MRAM, read only memory (ROM), erasable programmable ROM (EPROM), electrically erasable programmable ROM (EEROM), ferroelectric, magnetoresistive, and other storage media, including non-volatile, flash (e.g., NAND and/or NOR) storage media.

### A. Overview

Semiconductor memory devices may store information in an array of memory cells. The information may be stored as a binary code, and each memory cell may store a bit of information as either a logical high (e.g., a “1”) or a logical low (e.g., a “0”). The memory cells may be organized at the intersection of word lines (rows) and bit lines (columns). The memory may further be organized into one or more memory banks, each of which may include a plurality of rows and columns. During operations, the memory device may (a) receive a command and an address which specifies one or more rows and one or more columns and (b) execute the command on the memory cells corresponding to the address.

Although volatile memory devices typically begin to lose their stored data when power is no longer supplied to the memory devices, the data loss is not immediate and can be delayed/prolonged by cooling memory devices to low temperatures. As such, there is a risk that data stored to the volatile memory devices can be accessed without authorization by cooling the memory devices to low temperatures, quickly swapping the memory devices from one memory system to another, and then attempting to access the data stored to the memory devices.

To address these concerns, the present technology is generally directed to memory devices that include data destruction circuitry that, after the memory devices detect a data destruction condition, destroy data stored to the memory devices. Examples of data destruction conditions can include a memory device experiencing a power down event, a memory device experiencing a power loss event, or a memory device performing initialization (e.g., within a new power cycle of the memory device). Another example of a data destruction condition can be an internal temperature of a memory device dropping below a threshold temperature value (e.g., that indicates that the memory device is being cooled to delay/prolong data loss in the memory device after it is disconnected from power in an attempt to gain unauthorized access of data stored to the memory device).

In accordance with one aspect of the present disclosure, a memory device (or other apparatus) includes a memory array having memory cells arranged at intersections of word lines and bit lines, and word line drivers coupled to the word lines. The memory device can additionally comprise data destruction circuitry that includes one or more switches coupled to the word lines drivers. Each of the one or more switches can be configured to couple a corresponding word line driver to a first voltage source (e.g., a voltage source Vdd, a voltage source Vpp, or another suitable voltage source) or a second voltage source (e.g., a negative word line voltage generator or another suitable voltage source) based at least in part on a control signal output by a switch controller. The data destruction circuitry can additionally include a detector (e.g., a temperature sensor) configured to detect when a data destruction condition of the memory device is met.

Upon a determination that a data destruction condition has been met, the switch controller can control the one or more switches to couple the word line drivers to the first voltage source. In turn, the word lines drivers can drive voltages on the word lines to a first voltage that is usable to couple storage elements of the memory cells of the memory array to the bit lines. As the storage elements of the memory cells are coupled to the bit lines, each of the storage elements can be charged or discharged (e.g., depending on (i) the voltage and/or (ii) the data state of a data bit stored to the respective storage element), thereby destroying data stored to the storage elements for subsequent reads of the data. In some embodiments, the one or more switches of the data destruction circuitry couple every word line driver to the first voltage source such that every storage element included in the memory array is charged or discharged, thereby destroying data stored to every storage element of the memory array. In other embodiments, the one or more switches of the data destruction circuitry couple only a subset of the word line drivers to the first voltage source such that only a subset of the storage elements included in the memory array is charged or discharged, thereby destroying data stored to only a subset of the storage elements of the memory array. In some embodiments, before or while the storage elements are coupled to the bit lines, the bit lines can be charged to a voltage level (e.g., a mid-voltage level, a bit line precharge voltage VBLP, or a voltage level that does not correspond to a data state of data bits stored to the storage elements). After the data on all or a subset of the memory cells has been destroyed, the switch controller can control the one or more switches to (a) uncouple the word line drivers from the first voltage source and (b) couple the word line drivers to the second voltage source (e.g., to resume normal operations of the memory device).

The present technology is therefore expected to offer several advantages. For example, even though cooling a memory device configured in accordance with various embodiments of the present technology may decrease the rate of data loss following an interruption of power supplied to the memory device, the interruption of power (e.g., at any temperature) and/or a drop of an internal temperature of the memory device below a threshold value, can cause the memory device to operate the data destruction circuitry to destroy data stored to memory cells of the memory device (e.g., at the time the power is interrupted, upon initialization of the memory device, as soon as or after power is restored to the memory device). As a result, the memory device is expected to maintain security of data stored to the memory device across different power cycles of the memory device. Stated another way, while lowering the temperature of a memory device configured in accordance with various embodiments of the present technology may delay and/or prevent the memory device from irretrievably losing stored data while the memory device is swapped between systems, lowering the temperature does not enable access to the data stored to the memory device before the data destruction circuitry of the memory device destroys the data. Thus, the present technology is expected to thwart such attempts at accessing the data without authorization. Furthermore, in some embodiments of the present technology, new data destruction conditions can be defined, allowing the present technology to adapt or correspond to new or additional unauthorized attempts at accessing data stored to a corresponding memory device. Moreover, the data destruction circuitry described herein is relatively minimal, easy to implement, and relatively low-cost. Additionally, or alternatively, use of the data destruction circuitry is expected to provide robust data security with little to no operational drawbacks such as timing latency, increased power consumption, and/or increased complexity of user interactions.

### B. Selected Embodiments of Memory Systems and Associated Devices and Methods

FIG. 1A is a block diagram schematically illustrating a memory system 190 (e.g., a dual in-line memory module (DIMM)) configured in accordance with various embodiments of the present technology. In the illustrated embodiment, the memory system 190 includes a module or rank of memory devices 100 (identified individually as memory devices 100a-100h in FIG. 1A), a controller 101, and a host device 108. In some embodiments, the memory devices 100 can be DRAM memory devices. Although illustrated with a single module/rank of eight memory devices 100 in FIG. 1A, the memory system 190 can include a greater or lesser number of memory devices 100 and/or memory modules/ranks in other embodiments of the present technology. Well-known components of the memory system 190 have been omitted from FIG. 1A and are not described in detail below so as to avoid unnecessarily obscuring aspects of the present technology.

The memory devices 100 can be connected to one or more electronic devices that are capable of utilizing memory for temporary or persistent storage of information, or a component thereof. For example, one or more of the memory devices 100 can be operably connected to one or more host devices. As a specific example, the memory devices 100 of the memory system 190 illustrated in FIG. 1A are connected to a host device 101 (also referred to herein as a “memory controller 101” or “control circuit 101”) and to a host device 108 (also referred to herein as “CPU 108”).

The memory devices 100 of FIG. 1A are operably connected to the memory controller 101 via a command/address (CMD/ADDR) bus 118 and a data (DQ) bus 119. As described in greater detail below with respect to FIG. 1B, the CMD/ADDR bus 118 and the DQ bus 119 can be used by the memory controller 101 to communicate commands, memory addresses, and/or data to the memory devices 100. In response, the memory devices 100 can execute commands received from the memory controller 101. For example, in the event a write command is received from the memory controller 101 over the CMD/ADDR bus 118, the memory devices 100 can receive data from the memory controller 101 over the DQ bus 119 and can write the data to memory cells corresponding to memory addresses received from the memory controller 101 over the CMD/ADDR bus 118. As another example, in the event a read command is received from the memory controller 101 over the CMD/ADDR bus 118, the memory devices 100 can output data to the memory controller 101 over the DQ bus 119 from memory cells corresponding to memory addresses received from the memory controller 101 over the CMD/ADDR bus 118.

The host device 108 of FIG. 1A may be a computing device such as a desktop or portable computer, a server, a hand-held device (e.g., a mobile phone, a tablet, a digital reader, a digital media player), or some component thereof (e.g., a central processing unit, a co-processor, a dedicated memory controller, etc.). The host device 108 may be a networking device (e.g., a switch, a router, etc.); a recorder of digital images, audio, and/or video; a vehicle; an appliance; a toy; or any one of a number of other products. In one embodiment, the host device 108 may be connected directly to one or more of the memory devices 100 (e.g., via a communications bus of signal traces (not shown)). Additionally, or alternatively, the host device 108 may be indirectly connected to one or more of the memory device 100 (e.g., over a networked connection or through intermediary devices, such as through the memory controller 101 and/or via a communications bus 117 of signal traces).

As discussed further herein, each of the memory devices 100 can include circuitry (also referred to herein as “data destruction circuitry,” “data security circuitry,” “data security subsystems,” “data initialization circuitry,” “initialization circuitry,” and the like) for protecting data stored to the memory devices 100 from unauthorized access (e.g., following a power down or power loss event). For example, each of the memory devices 100 can include circuitry that can destroy, remove, or otherwise preempt access to stored data (e.g., such that the stored data cannot be accessed across different power cycles of the memory device). The circuitry can be configured to destroy, remove, or otherwise preempt access to the stored data upon determining that a data destruction condition has been met. In some embodiments, the data destruction condition can include (a) power supplied to the memory device 100 being interrupted (e.g., when the memory device 100 is restarted, when the memory device 100 is powered down, or when the memory device 100 experiences a power loss event), (b) the memory device 100 performing an initialization routine (e.g., within a new power cycle of the memory device 100), and/or (c) another indication of attempted access of stored data without authorization, such as an abnormally reduced internal temperature of the memory device 100.

FIG. 1B is a block diagram schematically illustrating one of the memory devices 100 configured in accordance with various embodiments of the present technology. The memory device 100 may include an array of memory cells, such as memory array 150. The memory array 150 may include a plurality of banks 152 (e.g., banks 0-15 in the example of FIG. 1B), and each bank may include a plurality of word lines (WL), a plurality of bit lines (BL), and a plurality of memory cells (e.g., m×n memory cells) arranged at intersections of the word lines (e.g., m word lines, which may also be referred to as rows) and the bit lines (e.g., n bit lines, which may also be referred to as columns).

Memory cells can include any one of a number of different memory media types, including capacitive, phase change, magnetoresistive, ferroelectric, or the like. The selection of a word line WL may be performed by a row decoder 140, and the selection of a bit line BL may be performed by a column decoder 145. The row decoder 140 can include a plurality of word line drivers 142 (also referred to herein as “word line driver circuits,” “WL drivers,” “WL driver circuits,” “driver circuits,” and the like) operably coupled to the memory array 150. Although shown as part of the row decoder 140 in FIG. 1B, the word line drivers 142 can be located at least partially elsewhere in the memory device 100 in other embodiments of the present technology, such as in the memory array 150. Each word line WL may be coupled with a corresponding word line driver 142 configured to control a voltage of the word line during memory operations. Sense amplifiers (SAMP) may be provided for corresponding bit lines BL and connected to at least one respective local I/O line pair (LIOT/B), which may in turn be coupled to at least one respective main I/O line pair (MIOT/B), via transfer gates (TG), which can function as switches. The memory array 150 may also include plate lines and corresponding circuitry for managing their operation.

The memory device 100 may employ a plurality of external terminals that include command and address terminals coupled to a command bus and address bus (e.g., the CMD/ADDR bus 118 of FIG. 1A) to receive command signals CMD and address signals ADDR, respectively. The memory device may further include a chip select terminal to receive a chip select signal CS, clock terminals to receive clock signals CK and CKF; data clock terminals to receive data clock signals WCK and WCKF; data terminals to receive data signals DQ, DQS or RDQS, DBI (for data bus inversion function), and DMI (for data mask inversion function); and power supply terminals to receive power supply potentials VDD, VSS, and VDDQ.

The power supply potentials VDD and VSS can be supplied to an internal voltage generator circuit 170. The internal voltage generator circuit 170 can generate various internal potentials VPP, VOD, VARY, VPERI, and the like based on the power supply potentials VDD and VSS. The internal potential VPP can be used in the row decoder 140, the internal potentials VOD and VARY can be used in the sense amplifiers included in the memory array 150, and the internal potential VPERI can be used in many other circuit blocks.

The power supply potential VDDQ can be provided to an input/output circuit 160 of the memory device 100, together with the power supply potential VSS. The power supply potential VDDQ can be the same potential as the power supply potential VDD in some embodiments of the present technology. The power supply potential VDDQ can be a different potential from the power supply potential VDD in other embodiments of the present technology. The dedicated power supply potential VDDQ can be used for the input/output circuit 160 so that power supply noise generated by the input/output circuit 160 does not propagate to the other circuit blocks.

The clock terminals and data clock terminals may be supplied with external clock signals and complementary external clock signals. The external clock signals CK, CKF, WCK, WCKF can be supplied to a clock input circuit 133. The CK and CKF signals can be complementary, and the WCK and WCKF signals can be complementary. Complementary clock signals can have opposite clock levels and transition between the opposite clock levels at the same time. For example, when a clock signal is at a low clock level a complementary clock signal is at a high level, and when the clock signal is at a high clock level the complementary clock signal is at a low clock level. Moreover, when the clock signal transitions from the low clock level to the high clock level the complementary clock signal transitions from the high clock level to the low clock level, and when the clock signal transitions from the high clock level to the low clock level the complementary clock signal transitions from the low clock level to the high clock level.

Input buffers included in the clock input circuit 133 can receive the external clock signals. For example, when enabled by a CKE signal from a command decoder 115 of the memory device 100, an input buffer can receive the CK and CKF signals and the WCK and WCKF signals. The clock input circuit 133 can receive the external clock signals to generate internal clock signals ICLK. The internal clock signals ICLK can be supplied to an internal clock circuit 130. The internal clock circuit 130 can provide various phase and frequency controlled internal clock signals based on the received internal clock signals ICLK received from the clock input circuit 133 and the clock enable signal CKE received from the command decoder 115.

For example, the internal clock circuit 130 can include a clock path (not shown in FIG. 1B) that receives the internal clock signal ICLK and provides various clock signals to the command decoder 115. The internal clock circuit 130 can further provide input/output (I/O) clock signals. The I/O clock signals can be supplied to the input/output circuit 160 and can be used as a timing signal for determining an output timing of read data and an input timing of write data. The I/O clock signals can be provided at multiple clock frequencies so that data can be output from and input into the memory device 100 at different data rates. A higher clock frequency may be desirable when high memory speed is desired. A lower clock frequency may be desirable when lower power consumption is desired. The internal clock signals ICLK can also be supplied to a timing generator 135 that can generate various internal clock signals.

The command terminals and address terminals may be supplied with an address signal and a bank address signal from outside the memory device 100. The address signal and the bank address signal supplied to the address terminals can be transferred, via a command/address input circuit 105, to an address decoder 110. The address decoder 110 can receive the address signals and supply a decoded row address signal (XADD) to the row decoder 140 (which may be referred to as a row driver), and a decoded column address signal (YADD) to the column decoder 145 (which may be referred to as a column driver). The address decoder 110 can also receive the bank address portion of the ADDR input and supply the decoded bank address signal (BADD) to both the row decoder 140 and the column decoder 145.

The command and address terminals may be supplied with command signals CMD, address signals ADDR, and chip select signals CS, from a memory controller. The command signals may represent various memory commands received from the memory controller (e.g., refresh commands, activate commands, precharge commands, access commands, which can include read commands and write commands). The chip select signal CS may be used to select the memory device 100 to respond to commands and addresses provided to the command and address terminals. When an active CS signal is provided to the memory device 100, the commands and addresses can be decoded and memory operations can be performed. The command signals CMD may be provided as internal command signals ICMD to the command decoder 115 via the command/address input circuit 105.

The command decoder 115 may include circuits to decode the internal command signals ICMD to generate various internal signals and commands for performing memory operations (e.g., a row command signal to select a word line and a column command signal to select a bit line). Other examples of memory operations that the memory device 100 may perform based on decoding the internal command signals ICMD includes a refresh command (e.g., re-establishing full charges stored in individual memory cells of the memory array 150), an activate command (e.g., activating a row in a particular bank, in some cases for subsequent access operations), or a precharge command (e.g., deactivating the activated row in the particular bank). The internal command signals can also include output and input activation commands, such as clocked command CMDCK (not shown in FIG. 1B).

The command decoder 115, in some embodiments, may further include one or more registers 128 for tracking various counts and/or values (e.g., counts of refresh commands received by the memory device 100 or self-refresh operations performed by the memory device 100) and/or for storing various operating conditions for the memory device 100 to perform certain functions, features, and modes (or test modes). As such, in some embodiments, the registers 128 (or a subset of the registers 128) may be referred to as mode registers. Additionally, or alternatively, the memory device 100 may include registers 128 as a separate component outside of the command decoder 115. In some embodiments, the registers 128 may include multi-purpose registers (MPRs) configured to write and/or read specialized data to and/or from the memory device 100.

When a read command is issued to a bank with an open row and a column address is timely supplied as part of the read command, read data can be read from memory cells in the memory array 150 designated by the row address (which may have been provided as part of the activate command identifying the open row) and column address. The read command may be received by the command decoder 115, which can provide internal commands to an input/output circuit 160 so that read data can be output from the data terminals DQ, DQS or RDQS, DBI, and DMI via read/write amplifiers 155 and the input/output circuit 160 according to the DQS or RDQS clock signals. The read data may be provided at a time defined by read latency information that can be programmed in the memory device 100, for example, in a mode register (e.g., one or more of the registers 128). The read latency information can be defined in terms of clock cycles of the clock signal CK. For example, the read latency information can be a number of clock cycles of the clock signal CK after the read command is received by the memory device 100 when the associated read data is provided.

When a write command is issued to a bank with an open row and a column address is timely supplied as part of the write command, write data can be supplied to the data terminals DQ, DBI, and DMI according to the WCK and WCKF clock signals. The write command may be received by the command decoder 115, which can provide internal commands to the input/output circuit 160 so that the write data can be received by data receivers in the input/output circuit 160, and supplied via the input/output circuit 160 and the read/write amplifiers 155 to the memory array 150. The write data may be written in the memory cell designated by the row address and the column address. The write data may be provided to the data terminals at a time that is defined by write latency information. The write latency information can be programmed in the memory device 100, for example, in a mode register (e.g., one or more of the registers 128). The write latency information can be defined in terms of clock cycles of the clock signal CK. For example, the write latency information can be a number of clock cycles of the clock signal CK after the write command is received by the memory device 100 when the associated write data is received.

In the illustrated embodiment, the memory device 100 includes data destruction circuitry 185. As shown, the data destruction circuitry 185 includes one or more switches 183. Although shown as part of the row decoder 140 in FIG. 1B, the one or more switches 183 can be located at least partially elsewhere in the memory device 100 in other embodiments of the present technology, such as in the memory array 150, in the address decoder 110, in the command decoder 115, and/or in the voltage generator circuit 170. As also shown in the illustrated embodiment, the data destruction circuitry 185 can further include a detector 187. Although shown as outside the row decoder 140 in FIG. 1B, the detector 187 can be a part of the row decoder 140 and/or can be positioned at other locations within or external to the memory device 100 in other embodiments of the present technology.

As discussed further herein, the data destruction circuitry 185 can be configured to, when a data destruction condition is met, control the word line drivers 142 (e.g., via the one or more switches 183) to drive voltages on the word lines WL to a desired voltage level (e.g., a high voltage level) to, for example, activate access transistors of the corresponding memory cells to charge or discharge the memory cells (e.g., to an indeterminate logic state). As a result, the data destruction circuitry 185 can effectively destroy, corrupt, make uninterpretable, or otherwise make inaccessible data stored on the corresponding memory cells.

In some embodiments, a data destruction condition can include the memory device 100 performing an initialization routine (e.g., within a new power cycle of the memory device 100). In such embodiments, the memory device 100 can, upon initialization of the memory device 100 (e.g., as detected by the detector 187 and/or after the memory device 100 experiences a power down event or a power loss event), trigger destruction of data stored to memory cells of the memory array 150 using the data destruction circuitry 185. In these and other embodiments, a data destruction condition can be an indication of attempted access of data stored to the memory device 100 without authorization, and the detector 187 can be configured to detect the indication. As a specific example, the detector 187 can include a temperature sensor configured to monitor the internal temperature of the memory device 100. Continuing with this example, the detector 187 can be used to detect when an internal temperature of the memory device 100 drops below a predetermined threshold. The predetermined threshold can be set at a temperature value below which it is likely that an attempt to gain access of the stored data without authorization is occurring. For example, the predetermined threshold can be set at a temperature value below internal temperature values of the memory device 100 that are typically observed within the memory device 100 during standard operation or use of the memory device 100, and/or at or below a temperature value that indicates the memory device 100 is likely being cooled to delay and/or prevent the memory device 100 from irretrievably losing stored data as it is swapped between systems. Thus, when the detector 187 determines that the internal temperature of the memory device 100 is at or below the predetermined threshold, the memory device 100 can trigger destruction of data stored to memory cells of the memory array 150 using the data destruction circuitry 185.

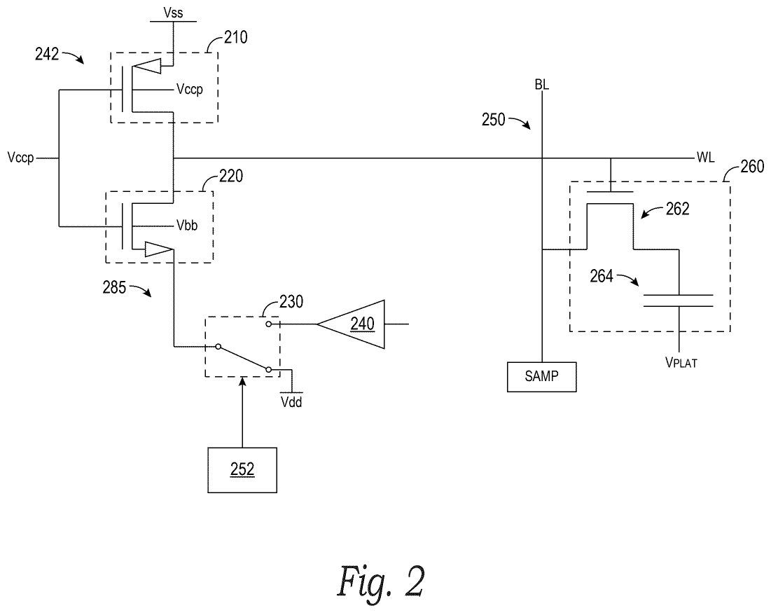

FIG. 2 illustrates a partially schematic diagram of data destruction circuitry 285 operably coupled to a word line driver 242, which is coupled to a memory cell 260 of a memory array 250, each configured in accordance with various embodiments of the present technology. The data destruction circuitry 285 can be the data destruction circuitry 185 of FIG. 1B or other data destruction circuitry configured in accordance with various embodiments of the present technology.

As shown, the data destruction circuitry 285 includes a switch 230 coupled to the word line driver 242. In the illustrated embodiment, the word line driver 242 includes a complementary metal-oxide-semiconductor (CMOS) inverter having a first transistor 210 (e.g., a p-type metal-oxide-semiconductor (PMOS) transistor), a second transistor 220 (e.g., an n-type metal-oxide-semiconductor (NMOS) transistor), an input coupled to the gates of the first transistor 210 and the second transistor 220, and an output coupled to the drain terminals of the first transistor 210 and the second transistor 220. The source terminal of the first transistor 210 can be coupled to a voltage source Vss, the body terminal of the first transistor 210 can be coupled to a voltage source Vccp, the input of the inverter can be coupled to the voltage source Vccp, the body terminal of the second transistor 220 can be coupled to a voltage source Vbb, and the output of the inverter can be coupled to a word line WL.

The source terminal of the second transistor 220 can be coupled to the switch 230 of the data destruction circuitry 285. As shown, the switch 230 is configured to couple the source terminal of the second transistor 220 (and hence the word line WL when the second transistor 220 is activated) to either (a) a negative word line voltage (VNWL) generator 240 or (b) a voltage source Vdd or another suitable voltage source. In the illustrated embodiment, the switch 230 is shown as a single pole double throw (SPDT) switch. In other embodiments, the switch 230 can have other configurations. For example, the switch 230 can comprise a transistor (e.g., a PMOS transistor) coupled between the word line WL and the VNWL generator 240, and a transistor (e.g., an NMOS transistor) coupled between the word line and the voltage source Vdd. Continuing with this example, the gates of the two transistor can be coupled together and/or receive a control signal usable to selectively activate the two transistors.

In some embodiments, the data destruction circuitry 285 further includes a switch controller 252 configured to control operation of the switch 230. In one example, the switch controller 252 can comprise a pulse generator configured to generate a pulse in a control signal that is usable to toggle the switch 230 between states. The control signal provided by the switch controller 252 can have multiple states, such as a high state and a low state. Continuing with this example, when the control signal is in the high state, the switch 230 can couple the source terminal of the second transistor 220 (and hence the word line WL when the second transistor 220 is activated) to the voltage source Vdd. Furthermore, when the control signal is in the low state, the switch 230 can couple the source terminal of the second transistor 220 (and hence the word line WL when the second transistor 220 is activated) to the VNWL generator 240. In other embodiments, the response of the switch to the high and low states of the control signal can be flipped.

Referring now to the memory cell 260 of the memory array 250, the memory cell 260 is positioned at an intersection of the word line WL and a bit line BL. As shown, the memory cell 260 can include a capacitor 264 and an access transistor 262 coupled between the capacitor 264 and the bit line BL. One plate of the capacitor 264 can be coupled to the access transistor 262, and the other plate of the capacitor 264 can be coupled to a voltage source VPLAT, a ground voltage source (e.g., voltage source Vss), or another suitable voltage source. A gate terminal of the access transistor 262 can be coupled to the word line WL such that the voltage on the word line WL is usable to selectively activate the access transistor 262 to couple the capacitor 264 to the bit line BL. Although only one memory cell 260 of the memory array 250 is shown in FIG. 2, it is appreciated (a) that the memory array 250 can include several instances of such memory cells and (b) that aspects of the present technology described above and below with respect to the memory cell 260 illustrated in FIG. 2 can equally apply to the other memory cells of the memory array 250. Additionally, or alternatively, although only one switch 230 and one word line driver 242 are shown in FIG. 2, it will be appreciated that the data destruction circuitry 285 (a) can include a plurality of switches and/or (b) can be coupled to (or include) multiple word line drivers 242, each word line driver 242 coupled to a corresponding word line WL of the memory device. Furthermore, although shown separate from the word line driver 242 in the illustrated embodiment, it will be appreciated that the data destruction circuitry 285 can include the word line driver 242 in some embodiments.

Operation of the data destruction circuitry 285 will now be described. Upon a determination that a data destruction condition has been met, the switch controller 252 can configure the switch 230 to couple the source terminal of the second transistor 220 to the voltage source Vdd, as shown in FIG. 2. For example, when a memory device that includes the data destruction circuitry 285 experiences a power down event or a power loss event, the switch controller 252 can, upon initialization of the memory device after power is restored, operate the switch 230 to couple the source terminal of the second transistor 220 to the voltage source Vdd. In another example, when a detector (e.g., the detector 187 of FIG. 1B) of the memory device detects that an internal temperature of the memory device is below a threshold temperature value, the switch controller 252 can operate the switch 230 to couple the source terminal of the second transistor 220 to the voltage source Vdd. In both of these examples, when the word line WL is coupled to the voltage source Vdd, the voltage on the word line WL can be driven toward a first voltage (e.g., the voltage Vdd). In some embodiments, the first voltage is a voltage level (e.g., 1 V, 1.1 V, 1.2 V, etc.) that is high enough to activate the access transistor 262 of the memory cell 260.

In some embodiments, before, during, or after activating the access transistor 262, the memory device can charge, precharge, or drive the bit line BL to a bit line precharge voltage VBLP. The bit line precharge voltage VBLP can be a voltage level (e.g., Vdd/2 or another suitable voltage level) that is less than a voltage corresponding to a first data state (e.g., a high or ‘1’ data state) but that is greater than a voltage corresponding to a second data state (e.g., a low or ‘0’ data state). Additionally, or alternatively, the bit line precharge voltage VBLP can be a reference voltage level used by the corresponding sense amplifier (SAMP) (e.g., during normal read operations of the memory device) to determine data states of data bits stored to memory cells that are coupled to the bit line BL. Thus, such a voltage level for the bit line precharge voltage VBLP can be considered a mid-voltage level or can be considered to correspond to an indeterminate voltage level or data state (e.g., a voltage level or data state that neither clearly corresponds to the first data state nor the second data state). In some embodiments, when the memory device determines that a data destruction condition has been met, the data destruction circuitry 285 can activate the access transistor 262 of the memory cell 260 without the memory device powering the corresponding sense amplifier (SAMP). In other embodiments, the memory device can power the corresponding sense amplifier (SAMP) while the data destruction circuitry 285 activates the access transistor 262 of the memory cell 260.

As the access transistor 262 is activated, the capacitor 264 of the memory cell 260 is coupled to the bit line BL. In the event that the capacitor 264 of the memory cell 260 is storing a voltage corresponding to the first data state (e.g., the high or ‘1’ data state), the voltage stored on the capacitor 264 can be greater than the bit line precharge voltage VBLP. Thus, when the capacitor 264 of the memory cell 260 is coupled to the bit line BL, the capacitor 264 can be discharged via the bit line BL, and the voltage on the capacitor 264 can decrease toward the bit line precharge voltage VBLP until the voltage on the capacitor 264 no longer clearly corresponds to the first data state and/or until the corresponding sense amplifier (SAMP) is unable to (e.g., consistently) determine a data state of the data bit stored to the capacitor 264. In other words, coupling the capacitor 264 of the memory cell 260 to the corresponding bit line BL while the bit line precharge voltage VBLP is less than the voltage stored on the capacitor 264 can destroy/corrupt the data bit stored on the memory cell 260 for subsequent reads of the memory cell 260.

Similarly, in the event the capacitor 264 of the memory cell 260 is storing a voltage corresponding to the second data state (e.g., the low or ‘0’ data state), the voltage stored on the capacitor 264 can be less than the bit line precharge voltage VBLP. Thus, when the capacitor 264 of the memory cell 260 is coupled to the bit line BL, the capacitor 264 can be charged via the bit line BL, and the voltage on the capacitor 264 can increase toward the bit line precharge voltage VBLP until the voltage on the capacitor 264 no longer clearly corresponds to the second data state and/or until the corresponding sense amplifier (SAMP) is unable to (e.g., consistently) determine a data state of the data bit stored to the capacitor 264. In other words, coupling the capacitor 264 of the memory cell 260 to the corresponding bit line BL while the bit line precharge voltage VBLP is greater than the voltage stored on the capacitor 264 can destroy/corrupt the data bit stored on the memory cell 260 for subsequent reads of the memory cell 260.

In some embodiments, the data destruction circuitry 285 is coupled to every word line driver 242 such that the voltages on every word line WL can be driven toward the first voltage (e.g., the voltage Vdd) and the data bits stored on every memory cell 260 of the memory array 250 can be destroyed/corrupted. In these and other embodiments, the switches 230 of the data destruction circuitry 285 can be controlled collectively, individually, and/or in groups. In embodiments in which the switches 230 can be controlled individually and/or in groups (e.g., representing less than all the switches 230 of the data destruction circuitry 285), the data destruction circuitry 285 can be used to control an individual word line driver 242 or a group of word line drivers 242 (e.g., representing less than all of the word line drivers 242) such that voltage(s) on the corresponding word line(s) WL can be driven toward the first voltage (e.g., the voltage Vdd) and the data bit(s) stored on the corresponding memory cell(s) 260 (e.g., representing less than all of the memory cells 260 of the memory array 250) can be destroyed/corrupted. In other embodiments, the data destruction circuitry 285 is coupled to only a subset of the word line drivers 242 of the memory device such that the voltages on only a subset of the word lines WLs can be driven toward the first voltage (e.g., the voltage Vdd) and the data bits stored on only a subset of the memory cells 260 of the memory array 250 can be destroyed/corrupted.

Once an amount of time (e.g., a predetermined amount of time expected to be suitable for adequately destroying/corrupting data stored on the memory cell 260) has elapsed since coupling the capacitor 264 to the bit line BL, the switch controller 252 can operate the switch 230 to couple source terminal of the second transistor 220 to the VNWL generator 240. For example, in embodiments in which the switch controller 252 includes a pulse generator, the switch 230 can couple the source terminal of the second transistor 220 to the VNWL generator 240 at a back edge (e.g., a falling edge) of a pulse provided by the pulse generator. As another example, the switch 230 can coupled the source terminal of the second transistor 220 to the VNWL generator 240 as the corresponding memory device begins receiving commands from a connected host device, at an end of or at another point within the memory device's initialization routine, as an internal temperature of the memory device 100 returns to at or above a predetermined temperature value, or upon the occurrence of one or more other events. Thereafter, the memory device 100 can be operated as normal (e.g., by writing data to or reading data from memory cells of the memory array 250).

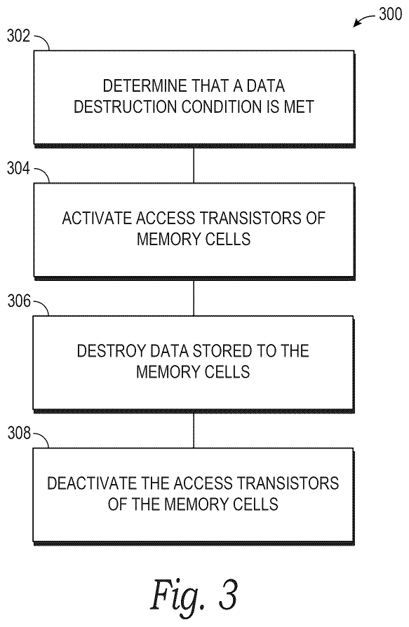

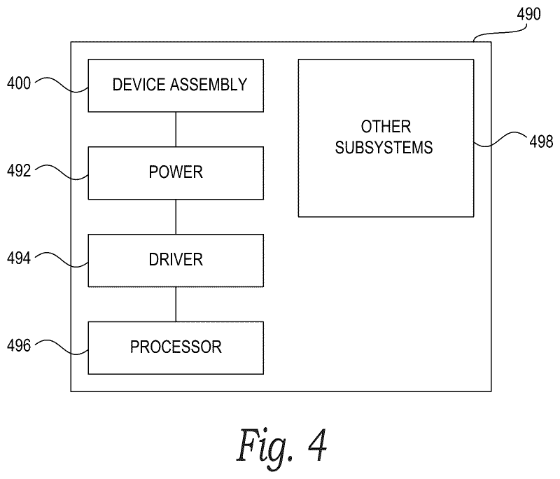

FIG. 3 is a flowchart illustrating a method 300 for destroying (or otherwise preempting access to) data in accordance with various embodiments of the present technology. The method 300 is illustrated as a set of steps or blocks 302, 304, 306, and 308. All or a subset of one or more of the blocks 302, 304, 306, and/or 308 can be executed in accordance with the discussion above and/or with the discussion of FIG. 4 below.

The method 300 begins at block 302 by determining that a data destruction condition is met. The data destruction condition can indicate that data stored in a memory device is to be destroyed. For example, the data destruction condition can be the memory device experiencing a power down event or a power loss event. As another example, the data destruction condition can be initialization of the memory device (e.g., within a new power cycle of the memory device). As still another example, the data destruction condition can be an internal temperature of the memory device dropping below a predetermined threshold temperature value.

At block 304, the method 300 continues by activating access transistors of memory cells of a memory array of the memory device. Activating the access transistors can include driving corresponding word lines toward a first voltage. Driving the corresponding word lines toward the first voltage can include driving the corresponding word lines toward the first voltage using corresponding word line drivers. Additionally, or alternatively, driving the corresponding word lines toward the first voltage can include controlling a switch to couple the corresponding word line drivers to a first voltage source (e.g., a voltage source Vdd). In some embodiments, controlling the switch comprises configuring a pulse generator operably coupled to the switch to generate a pulse. In these embodiments, the switch can couple the corresponding word line drivers to the first voltage source based at least in part on (or in response to) the pulse. Activating the access transistors can include coupling capacitors or other storage elements of the memory cells to corresponding bit lines.

At block 306, the method 300 continues by destroying data stored to the memory cells. Destroying the data can include discharging the capacitors/storage elements of at least a first subset of the memory cells or decreasing a voltage stored on the capacitors/storage elements. The first subset of memory cells can include memory cells storing voltages corresponding to a first data state (e.g., a high or ‘1’ data state). Additionally, or alternatively, destroying the data can include charging the capacitors/storage elements of at least a second subset of the memory cells or increasing a voltage stored on the capacitors/storage elements. The second subset of the memory cells can include memory cells storing voltages corresponding to a second data state (e.g., a low or ‘0’ data state). In these and other embodiments, destroying the data can include changing voltages stored on the capacitors/storage elements of the memory cells to voltage levels that (i) neither correspond to the first data state nor the second data state and/or (ii) that make it difficult for corresponding sense amplifiers (SAMP) to (e.g., consistently) accurately determine data states of data bits stored on the capacitors/storage elements.

At block 308, the method 300 continues by deactivating the access transistors of memory cells. Deactivating the access transistors can include driving corresponding word lines toward a second voltage. Driving the corresponding word lines to the second voltage can include driving the corresponding word lines toward the second voltage using corresponding word line drivers. Additionally, or alternatively, driving the corresponding word lines to the second voltage can include controlling the switch to couple the corresponding word line drivers to a second voltage source. In some embodiments, second voltage source can be a generator, such as a VNWL generator. In these and other embodiments, controlling the switch can include controlling the switch after a (e.g., predetermined) period of time has elapsed, such as an amount of time that starts from when the access transistors are activated and/or that is expected to be suitable for adequately destroying/corrupting data stored to the memory cells.

Although the blocks 302, 304, 306, and 308 of the method 300 are discussed and illustrated in a particular order, the method 300 illustrated in FIG. 3 is not so limited. In other embodiments, the method 300 can be performed in a different order. In these and other embodiments, any of the blocks 302, 304, 306, and 308 of the method 300 can be performed before, during, and/or after any of the other blocks 302, 304, 306, and 308 of the method 300. Moreover, a person of ordinary skill in the relevant art will recognize that the illustrated method 300 can be altered and still remain within these and other embodiments of the present technology. For example, one or more of the blocks 302, 304, 306, and 308 of the method 300 illustrated in FIG. 3 can be omitted and/or repeated in some embodiments. As another example, the method 300 can include additional blocks in other embodiments than shown in FIG. 3. As a specific example, the method can include a block directed to charging (e.g., precharging, driving) a bit line precharge voltage VBLP toward a desired voltage (e.g., Vdd/2 or another suitable voltage) before, during, or after (a) determining that a data destruction condition is met (block 302), (b) activating the access transistor of the memory cells (block 304), and/or (c) destroying the data stored to the memory cells (block 306).

FIG. 4 is a schematic view showing a system 400 comprising a semiconductor device assembly 402 that can include memory devices configured in accordance with an embodiment of the present technology. Semiconductor device assemblies including the memory devices described above with reference to FIGS. 1A-3 can be incorporated into any of a myriad of larger and/or more complex systems, such as the system 400 illustrated. The system 400 can include the semiconductor device assembly 402 (e.g., or a discrete semiconductor device), a power source 404, a driver 406, a processor 408, and/or other subsystems or components 410. The semiconductor device assembly 402 can include memory devices with features generally similar to those of the memory devices described above with reference to FIGS. 1A-3, such as the word line driver 142 (which can include the switch 230, the VNWL generator 240, and the switch controller 252) and the detector 187. The resulting system 400 can perform any of a wide variety of functions, such as memory storage, data processing, and/or other suitable functions. Accordingly, representative systems 400 can include, without limitation, hand-held devices (e.g., mobile phones, tablets, digital readers, and digital audio players), computers, vehicles, appliances, and other products. Components of the system 400 may be housed in a single unit or distributed over multiple, interconnected units (e.g., through a communications network). The components of the system 400 can also include remote devices and any of a wide variety of computer readable media. As discussed herein, the semiconductor device assemblies with memory devices configured in accordance with embodiments of the present technology are expected to protect stored data across power cycles of the memory devices and/or from other attempts at accessing the stored data without authorization.

### Conclusion

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Further, the terms “approximately” and “about” are used herein to mean within at least within 10% of a given value or limit. Purely by way of example, an approximate ratio means within 10% of the given ratio.

Several implementations of the disclosed technology are described above in reference to the figures. The computing devices on which the described technology may be implemented can include one or more central processing units, memory, input devices (e.g., keyboard and pointing devices), output devices (e.g., display devices), storage devices (e.g., disk drives), and network devices (e.g., network interfaces). The memory and storage devices are computer-readable storage media that can store instructions that implement at least portions of the described technology. In addition, the data structures and message structures can be stored or transmitted via a data transmission medium, such as a signal on a communications link. Various communications links can be used, such as the Internet, a local area network, a wide area network, or a point-to-point dial-up connection. Thus, computer-readable media can comprise computer-readable storage media (e.g., “non-transitory” media) and computer-readable transmission media.

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments.

Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

What is claimed is:

1. A memory device, comprising:
a memory array including a plurality of word lines, a plurality of bit lines, and a plurality of memory cells arranged at intersections of the plurality of word lines with the plurality of bit lines;
a plurality of word line drivers each coupled to a corresponding one of the plurality of word lines; and
data destruction circuitry including one or more switches configured to selectively couple the plurality of word line drivers to a first voltage source or a second voltage source different from the first voltage source,
wherein the data destruction circuitry is configured to, upon a determination that a data destruction condition has been met, selectively couple the plurality of word line drivers to the first voltage source via the one or more switches such that (i) each of the plurality of word line drivers drives the corresponding one of the plurality of word lines toward a first voltage, (ii) the first voltage is used to couple storage elements of the plurality of memory cells to corresponding ones of the plurality of bit lines, and (iii) the storage elements are charged or discharged via the corresponding ones of the plurality of bit lines such that data stored on the memory cells is destroyed.

2. The memory device of claim 1, wherein the data destruction condition includes an initialization of the memory device, the memory device experiencing a power down event, or the memory device experiencing a power loss event.

3. The memory device of claim 1, wherein the data destruction condition includes an internal temperature of the memory device dropping below a threshold temperature value, and wherein the data destruction circuitry further includes a temperature sensor configured to monitor the internal temperature of the memory device.

4. The memory device of claim 1, wherein the first voltage source includes a voltage source configured to supply a voltage Vdd.

5. The memory device of claim 1, wherein the second voltage source includes a negative word line voltage generator configured to supply a negative word line voltage (VNWL).

6. The memory device of claim 1, wherein the data destruction circuitry further includes a switch controller, and wherein the one or more switches are configured to selectively couple the plurality of word line drivers to the first voltage source or the second voltage source based at least in part on a control signal output by the switch controller.

7. The memory device of claim 6, wherein the switch controller includes a pulse generator.

8. The memory device of claim 1, wherein:
the plurality of memory cells includes every memory cell of the memory array;
the plurality of word line drivers includes every word line driver coupled to the plurality of word lines; and
the data destruction circuitry is configured to, upon the determination that the data destruction condition has been met, selectively couple the plurality of word line drivers to the first voltage source via the one or more switches such that (i) voltages on every word line of the plurality of word lines is driven toward the first voltage, (ii) the first voltage is used to couple every storage element of the plurality of memory cells to corresponding ones of the plurality of bit lines, and (iii) every storage element is charged or discharged via the corresponding ones of the plurality of bit lines such that data stored on every memory cell of the memory array is destroyed.

9. A method, comprising:
determining that a data destruction condition is met, wherein the data destruction condition indicates that data stored in memory cells of a memory device is to be destroyed; and
based at least in part on the determination, controlling a plurality of word lines such that storage elements of the memory cells are coupled to corresponding bit lines such that the storage elements are charged or discharged via the corresponding bit lines to drive voltages on the storage elements toward a voltage level that destroys the data stored in the memory cells.

10. The method of claim 9, wherein controlling the plurality of word lines includes controlling one or more switches to couple a plurality of word line drivers corresponding to the plurality of word lines to a first voltage source such that voltages on word lines of the plurality of word lines are driven toward a first voltage that is usable to couple the storage elements of the memory cells to the corresponding bit lines.

11. The method of claim 10, wherein controlling the one or more switches includes outputting a pulse from a pulse generator.

12. The method of claim 10, further comprising, after controlling the one or more switches to couple the plurality of word line drivers to the first voltage source, controlling the one or more switches to (a) uncouple the plurality of word line drivers from the first voltage source and (b) couple the plurality of word line drivers to a second voltage source different from the first voltage source.

13. The method of claim 12, wherein controlling the one or more switches to couple the plurality of word line drivers to the second voltage source includes controlling the one or more switches to couple the plurality of word line drivers to a negative word line voltage generator.

14. The method of claim 12, wherein controlling the one or more switches to couple the plurality of word line drivers to the second voltage source includes controlling the one or more switches to couple the plurality of word line drivers to the second voltage source after a predetermined amount of time has elapsed since controlling the one or more switches to couple the plurality of word line drivers to the first voltage source.

15. The method of claim 9, wherein determining that the data destruction condition is met includes detecting an initialization of the memory device, detecting a power down event of the memory device, or detecting a power loss event of the memory device.

16. The method of claim 9, wherein determining that the data destruction condition is met includes detecting that an internal temperature of the memory device has dropped below a threshold temperature value.

17. The method of claim 9, wherein the voltage level that destroys the data stored in the memory cells is a mid-voltage level that does not correspond to a data state of data bits of the data that are stored to the memory cells before coupling the storage elements to the corresponding bit lines based at least in part on the determination, and wherein the method further comprises charging the corresponding bit lines to the mid-voltage level before or while coupling the storage elements of the memory cells to the corresponding bit lines based at least in part on the determination.

18. A memory device, comprising:
a memory array including a plurality of memory cells, each memory cell of the plurality of memory cells coupled to a corresponding word line of a plurality of word lines and a corresponding bit line of a plurality of bit lines,
wherein the memory device is configured to:
detect that a data destruction condition is met, wherein the data destruction condition indicates that data stored in memory cells of the plurality of memory cells is to be destroyed, and
based at least in part on detecting that the data destruction condition is met-control the plurality of word lines to couple storage elements of the memory cells to corresponding bit lines of the plurality of bit lines, wherein controlling the plurality of word lines includes driving voltages on the plurality of word lines toward a first voltage; and
charge or discharge the storage elements, via the corresponding bit lines, such that the data stored in the memory cells is destroyed.

19. The memory device of claim 18, further comprising one or more switches and one or more word line drivers coupled to the plurality of word lines, wherein driving the voltages on the plurality of word lines includes controlling the one or more switches to couple the one or more word line drivers to a first voltage supply.

20. The memory device of claim 18, wherein the data destruction condition includes initialization of the memory device or an internal temperature of the memory device that is below a threshold temperature value.
